(19) United States
(12) Patent Application Publication
(10) Pub. No.: US 2017/0141409 A1
(43) Pub. Date: May 18, 2017

(54) COATING METHOD OF SEPARATOR FOR FUEL CELL AND SEPARATOR FOR FUEL CELL

(71) Applicants: Universitat Zu Koln, Cologne (DE); Hyundai Motor Company, Seoul (KR)

(72) Inventors: Bokyung Kim, Yongin-si (KR); Yoo Chang Yang, Gunpo-si (KR); Suk Min Baeck, Seongnam-si (KR); Chi Seung Lee, Yongin-si (KR); Kwang Hoon Choi, Yongin-si (KR); In Woong Lyo, Suwon-si (KR); Jiyoun Seo, Suwon-si (KR); Sanjay Mathur, Cologne (DE); Yakup Gonullu, Cologne (DE); Andreas Mettenboerger, Cologne (DE); Thomas Fischer, Cologne (DE)

(73) Assignees: Hyundai Motor Company, Seoul (KR); Universitat Zu Koln, Cologne (DE)

(21) Appl. No.: 14/965,198

(22) Filed: Dec. 10, 2015

(30) Foreign Application Priority Data
Nov. 16, 2015 (KR) 10-2015-0160340

(51) Int. Cl. H01M 8/0228; C23C 16/50

(52) U.S. Cl. CPC H01M 8/0228; C23C 16/50; H01M 2250/20

(57) ABSTRACT

A method for coating a separator for a fuel cell is provided that includes vaporizing a metal carbide precursor to obtain a precursor gas; introducing a metal carbide coating layer-forming gas including the precursor gas in a reaction chamber; and applying a voltage to the reaction chamber so that the precursor gas is changed into a plasma state, thereby forming a metal carbide coating layer on either surface or both surfaces of a substrate. In this case, the metal carbide precursor may include a compound having a substituted or non-substituted cyclopentadienyl group.

### CROSS-REFERENCE TO RELATED APPLICATIONS

This application claims priority to and the benefit of Korean Patent Application No. 10-2015-0160340 filed on Nov. 16, 2015, which is incorporated herein by reference in its entirety.

### FIELD

The present disclosure relates to a method for coating a separator for a fuel cell and a separator for a fuel cell.

### BACKGROUND

The statements in this section merely provide background information related to the present disclosure and may not constitute prior art.

A fuel cell stack may be divided into repeatedly stacked parts, such as an electrode membrane, a separator, a gas diffusion layer, and a gasket, and non-repeated parts, such as an engaging system required for the engagement of a stack module, an encloser for protecting a stack, a part for providing an interface with a vehicle, and a high voltage connector. A fuel cell stack is a system in which hydrogen reacts with oxygen in air to emit electricity, water, and heat. In such a fuel cell stack, high-voltage electricity, water, and hydrogen coexist at the same place, and thus it has challenges.

Particularly, in the case of a fuel cell separator, since positive hydrogen ions generated during the operation of a fuel cell directly contact therewith, an anti-corrosive property is highly required. When using a metal separator without surface treatment, metal corrosion occurs and an oxide produced on the metal surface functions as an electrical insulator leading to degradation of electrical conductivity. In addition, the positive metal ions dissociated and released at that time contaminate an MEA (Membrane Electrode Assembly), resulting in degradation of the performance of a fuel cell.

In the case of a carbon-based separator that is currently used as a fuel cell separator, there is a risk in that cracks generated during its processing may remain in the inner part of a fuel cell, so there is a difficulty in forming a thin film in view of its strength and gas permeability, and it has a problem in terms of processability or the like.

In the case of a metal separator, while it shows favorable moldability and productivity by virtue of its excellent ductility and allows thin film formation and downsizing of a stack, it may cause contamination of an MEA due to corrosion and an increase in contact resistance due to the formation of an oxide film on the surface thereof, resulting in deterioration of the performance of a stack.

### SUMMARY

An exemplary form of the present disclosure provides a method for coating a separator for a fuel cell.

Another exemplary form of the present disclosure provides a separator for a fuel cell.

A coating method of a separator for a fuel cell according to an exemplary form of the present disclosure includes vaporizing a metal carbide precursor to obtain a precursor gas; introducing a metal carbide coating layer-forming gas including the precursor gas in a reaction chamber; and applying a voltage to the reaction chamber so that the precursor gas is changed into a plasma state, thereby forming a metal carbide coating layer on either surface or both surfaces of a substrate.

The metal carbide precursor may include a compound having a substituted or non-substituted cyclopentadienyl group.

The metal carbide may be a titanium carbide, a chromium carbide, a molybdenum carbide, a tungsten carbide, a copper carbide, or a niobium carbide, among others.

The metal carbide precursor may include a compound represented by Chemical Formula 1.

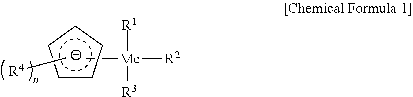

here, Me can be Ti, Cr, Mo, W, Cu, or Nb)

R¹ to R³ are independently a substituted or non-substituted C1 to C30 alkyl group, C3 to C30 cycloalkyl group, a C6 to C30 aryl group, C2 to C30 heteroaryl group, a C1 to C10 alkoxy group, a C1 to C10 amino alkyl group,

N is 0 to 4,

R⁴ is a C1 to C30 alkyl group, when n is 2 or more, a plurality of R⁴ may be equal to or different from each other.

The metal carbide precursor may include (trimethyl) pentamethyl cyclopentadienyl titanium, cyclopentadienyl (cycloheptyltrienyl) titanium, tris (dimethylamino) titanium cyclopentadienyl ride, or cyclopentadienyl tris (isopropoxide) titanium.

The metal carbide precursor may be vaporized to obtain the precursor gas in a temperature range of 50° C. to 100° C.

The metal carbide coating layer may be formed in a temperature range of 80° C. to 150° C.

A separator for a fuel cell according to an exemplary form is obtained by the above-described method and includes a substrate and a metal carbide coating layer formed on one surface or both surfaces of the substrate, wherein the metal carbide coating layer includes a metal carbide of 5 at % to 50 at % and a metal oxide of 0.01 at % to 15 at %.

A thickness of the metal carbide coating layer may be in a range of 50 nm to 1000 nm.

According to an exemplary form of the present disclosure, it is possible to form a coating layer at a low temperature, thereby reducing deformation of a substrate.

According to an exemplary form of the present disclosure, it is possible to form a coating layer at a low temperature, thereby saving production costs.

According to an exemplary form of the present disclosure, it is possible to form a coating layer through a PECVD (Plasma Enhanced Chemical Vapor Deposition) process, and thus to form a coating layer even in the case of a large area and mass production.

According to an exemplary form of the present disclosure, by using the compound having the substituted or non-substituted cyclopentadienyl group as the metal carbide precursor, the coating layer having an excellent corrosion resistance and an excellent conductivity may be formed.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a schematic view illustrating a PECVD (Plasma Enhanced CVD) system for forming a coating layer on a separator for a fuel cell according to an exemplary of the present disclosure;

FIG. 2 is an analysis graph of an X ray photoelectron spectroscopy (XPS) for a carbon coating layer of a separator for a fuel cell manufactured in an exemplary form of the present disclosure; and

FIG. 3 is an analysis graph of an X ray photoelectron spectroscopy (XPS) for a carbon coating layer of a separator for a fuel cell manufactured in an exemplary form of the present disclosure;

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

As used herein, unless otherwise defined, “substituted” refers to a group substituted with a C1 to C30 alkyl group; a C1 to C10 alkylsilyl group; a C3 to C30 cycloalkyl group; a C6 to C30 aryl group; a C2 to C30 heteroaryl group; a C1 to C10 alkoxy group; a fluoro group; a C1 to C10 trifluoroalkyl group such as trifluoromethyl group; or a cyano group.

As used herein, unless otherwise defined, “combination thereof” means two or more substituents bound to each other via a linking group, or two or more substituents bound to each other by condensation.

As used herein, unless otherwise defined, “alky group” means “saturated alkyl group” having no alkene or alkyne group. The “alkene group” means a substituent having at least two carbon atoms bound to each other via at least one carbon-carbon double bond, and “alkyne group” means a substituent having at least two carbon atoms bound to each other via at least one carbon-carbon triple bond. The alkyl group may be branched, linear, or cyclic.

The alkyl group may be a C1 to C20 alkyl group, more particularly a C1 to C6 lower alkyl group, a C7 to C10 medium alkyl group, or a C11 to C20 higher alkyl group.

For example, a C1 to C4 alkyl group means an alkyl group having 1 to 4 carbon atoms in its alkyl chain, and is selected from the group consisting of methyl, ethyl, propyl, isopropyl, n-butyl, isobutyl, sec-butyl, and t-butyl.

Typical alkyl groups includes methyl, ethyl, propyl, isopropyl, butyl, isobutyl, a t-butyl group, a pentyl group, a hexyl group, a cyclopropyl group, a cyclobutyl group, a cyclopentyl group, a cyclohexyl group and the like.

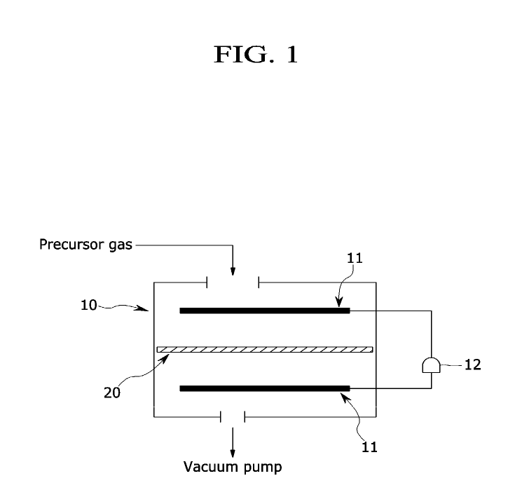

FIG. 1 is a schematic view illustrating a PECVD (Plasma Enhanced CVD) system for forming a coating layer on a separator for a fuel cell according to an exemplary form of the present disclosure.

Referring to FIG. 1, the PECVD system used in an exemplary form of the present disclosure is maintained under vacuum, and includes a reaction chamber 10 in which plasma can be formed, and a gas supply device for supplying a precursor gas in the reaction chamber.

In addition, the reaction chamber 10 is connected to a vacuum pump for forming vacuum in the chamber, and has a substrate (separator) 20 between electrodes 11 disposed in the reaction chamber 10. When power is supplied from a power supply device 12, the gases in the reaction chamber are converted into a plasma state. The gases present in a plasma state undergo polymerization on the surface of the substrate 20, thereby forming a coating layer.

The method for coating a separator for a fuel cell according to an exemplary form of the present disclosure may include the steps of: vaporizing a metal carbide precursor to obtain a precursor gas; introducing a metal carbide coating layer-forming gas containing the precursor gas into a reaction chamber; applying a voltage to the reaction chamber so that the precursor gas may be converted into a plasma state, thereby forming a metal carbide coating layer on a either surface or both surfaces of the substrate. In this case, the metal carbide precursor may include a compound having a substituted or non-substituted cyclopentadienyl group.

First, the precursor gas is formed by vaporizing the metal carbide (MeC) precursor.

The metal carbide precursor includes the compound having the substituted or non-substituted cyclopentadienyl group. As the metal carbide precursor, by using the compound having the substituted or non-substituted cyclopentadienyl group, a content of the metal carbide may be increased in the carbide coating layer. By increasing the content of the metal carbide, the electric conductivity of the separator for the fuel cell and the corrosion resistance may be simultaneously improved. The substituted or non-substituted cyclopentadienyl group may be a C5 to C20 substituted or non-substituted cyclopentadienyl group.

In detail, the metal carbide precursor may be a titanium carbide, a chromium carbide, a molybdenum carbide, a tungsten carbide, a copper carbide, or a niobium carbide precursor. In detail, the metal carbide precursor may include a compound represented by Chemical Formula 1.

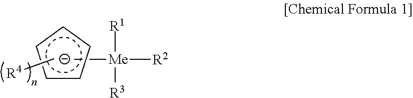

Here, Me may be Ti, Cr, Mo, W, Cu, or Nb, R¹ to R³ may be, independently, a C1 to C30 alkyl group, a C3 to C30 cycloalkyl group, a C6 to C30 aryl group, a C2 to C30 heteroaryl group, a C1 to C10 alkoxy group, a C1 to C10 amino alkyl group, n may be 0 to 4, and R⁴ may be a C1 to C30 alkyl group, when n is 2 or more, a plurality of R⁴ may be equal to or different from each other.

In detail, the metal carbide precursor may include (trimethyl) pentamethyl cyclopentadienyl titanium, cyclopentadienyl (cycloheptatrienyl) titanium, tris (dimethylamino) titanium cyclopentadienylide, or cyclopentadienyl tris (isopropoxide) titanium.

The metal carbide precursor may be vaporized at 50° C. to 100° C. When the temperature is excessively low, vaporization cannot be carried out smoothly. On the other hand, when the temperature is excessively high, the metal precursor may be degraded to cause a variation in the characteristics of the precursor itself so that its desired characteristics may not be realized and issues such as dust generation may occur. The pressure when the metal carbide precursor is vaporized may maintain 0.1 mTorr to 10 mTorr. The metal carbide precursor undergoes preliminary decomposition of ligands simultaneously with vaporization.

Next, the metal carbide coating layer-forming gas including the precursor gas is introduced in the reaction chamber. Herein, the precursor gas may be introduced through a pressure difference in the chamber by maintaining the pressure inside the reaction chamber at 10 mTorr to 1000 mTorr, while the reactive gas may be introduced at 100 sccm to 500 sccm.

The metal carbide coating layer-forming gas may further include an inert gas and a hydrogen gas. The inert gas may be Ar. The inert gas functions to activate the plasma and the hydrogen gas functions to decompose the precursor. The inert gas may be introduced at 100 sccm to 500 sccm, and the hydrogen gas may be introduced at 500 sccm to 1500 sccm. The coating is smoothly executed in the above-described range.

Next, the voltage is applied to the reaction chamber to change the precursor gas into a plasma state, thereby forming the metal carbide coating layer in the either surface or both surfaces of the substrate.

In this case, the voltage may be 400V to 800V. Also, the temperature may be controlled with 80° C. to 150° C. If the temperature is very low, the vaporized precursor is condensed, or the decomposition of the precursor may be incomplete, resulting in the issue of an increase in contact resistance. When the temperature is excessively high, the substrate may be deformed. Therefore, the temperature may be controlled within the above-defined range. The metal carbide coating layer may be formed during 10 min to 1 hr. In the case of a precursor, the initial gas generated after heating is not used to improve the reliability, and thus the deposition of a coating layer is carried out after the passage of at least 1 h. Then, deposition is carried out for at least 10 min for the purpose of stable activation of plasma. In this manner, it is possible to form a stable metal carbide coating layer-forming. In the case of the metal carbide coating layer, it realizes its characteristics in proportion to thickness rather than time, and the coating thickness varies with an increase in processing time. However, the coating layer realizes the same characteristics at a specific thickness after deposition, and thus there is little benefit for depositing a coating layer beyond such specific thickness.

As the manufactured metal carbide coating layer uses the compound having the substituted or non-substituted cyclopentadienyl group as the precursor, the content of the metal carbide is high and the content of the metal oxide is decreased. In detail, the content of the metal carbide may be 5 at % to 50 at %, and the content of the metal oxide may be 0.01 at % to 15 at %. Since the content of the metal carbide is increased and the content of the metal oxide is decreased, the electric conductivity and the corrosion resistance of the separator for the fuel cell may be simultaneously satisfied. The chamber is maintained in a vacuum state to suppress surface oxidation, and in one form, a robot is used to allow a sample to move in the chamber. In detail, the metal carbide coating layer may include the metal carbide of 20 at % to 40 at % and the metal oxide of 0.1 at % to 10 at %.

The thickness of the metal carbide coating layer can be controlled to a desired range by adjusting the conditions including the flow rate of the metal carbide coating layer-forming gas, applied voltage, temperature, and time. In detail, the thickness of the metal carbide coating layer may be 50 nm to 1000 nm. When the thickness is excessively small, it is not likely to sufficiently improve the anti-corrosive property. When the thickness is excessively large, contact resistance may increase, resulting in deterioration of conductivity. Accordingly, the thickness of the metal carbide coating layer may be adequately controlled. In detail, the thickness of the metal carbide coating layer may be 100 nm to 500 nm.

The separator for a fuel cell according to an exemplary form of the present disclosure has an excellent anti-corrosive property and conductivity, and thus may be advantageously used in a fuel cell.

The following examples illustrate the present disclosure in more detail. However, the following exemplary forms are for illustrative purposes only, and the scope of the present disclosure is not limited thereto.

Exemplary Form

For tris (isopropoxide), titanium chloride 1mol, cyclopentadienyl sodium is added by 1.2 mol and reacted while agitated during one hour at 80° C. After refining, as an analyzing result of the X rays photoelectron spectroscopy (XPS), a peak for CH₃, CH, cyclopentadienyl is confirmed in 1.11, 4.45, 6.13 ppm. An integral ratio of each peak is calculated in about 18:3:5 of 182.6:31.7:50.4, it is confirmed that the cyclopentadienyl tris (isopropoxide)titanium is synthesized in a purity of 99%.

The synthesized cyclopentadienyl tris (isopropoxide)titanium is heated in 1 mTorr, 65° C. to be vaporized, thereby forming the precursor gas.

As the substrate, stainless steel (SUS316L) having a thickness of 0.1 t was prepared. The substrate was subjected to washing with ultrasonic waves using ethanol and acetone to remove foreign materials on the substrate surface, and then treated with 5% DHF for 5 min to remove a surface oxide film (Cr₂O₃).

Next, the precursor gas 300 ccm is injected in the reaction chamber. In the this case, the pressure of the reaction chamber as 100 mTorr of the temperature of 100° C. are maintained.

Then, a voltage of 600 V was applied to the reaction chamber so that the gases could be converted into a plasma state, and deposition was carried out on the both surfaces of the substrate to form a titanium nitride (TiN) coating layer with a thickness of 300 nm.

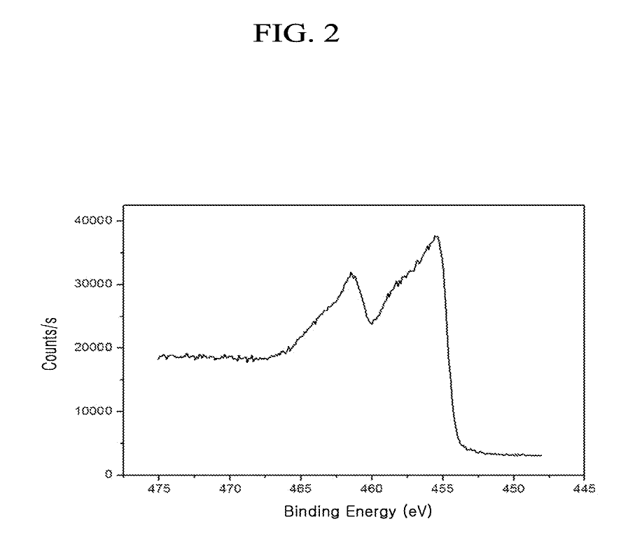

A result analyzing the titanium carbide coating layer by the X rays photoelectron spectroscopy (XPS) is represented in FIG. 2, the amount of the titanium carbide and the titanium oxide based on the total atomic weight of titanium in the front surface and the rear surface of the titanium carbide coating layer is summarized in Table 1. The hardness of the titanium carbide coating layer of the front surface and the rear surface of the titanium carbide coating layer is measured and is summarized in Table 1.

### COMPARATIVE EXAMPLE

As the precursor, instead of cyclopentadienyl tris (isopropoxide)titanium, except for using tetrakis (dimethylamido)titanium (TDMAT), it is the same as the above-described exemplary form.

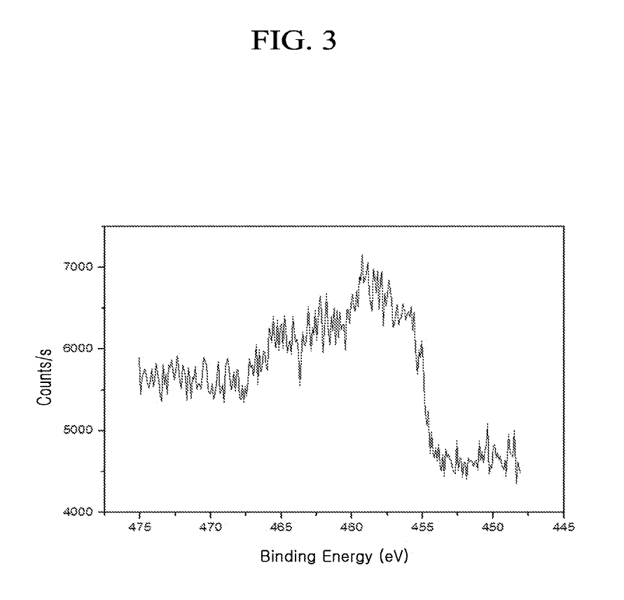

A result analyzing the titanium carbide coating layer by the X rays photoelectron spectroscopy (XPS) is represented in FIG. 3, the amount of the titanium carbide and the titanium oxide based on the total atomic weight of titanium in the front surface and the rear surface of the titanium carbide coating layer is summarized in Table 1. The hardness of the titanium carbide coating layer of the front surface and the rear surface of the titanium carbide coating layer is measured and is summarized in Table 1.

### EXPERIMENTAL EXAMPLE 1

### Measuring a Corrosion Current

The separator for the fuel cell manufactured in the exemplary form and the comparative example was evaluated to determine its corrosion current by using a potentiodynamic polarization test

First, a corrosive solution containing 10.78 g of sulfuric acid, 35 μl of hydrofluoric acid, and 2 l of ultrapure water was prepared. The manufactured separator for a fuel cell was provided in the form of a sample having a diameter of 16 mm and immersed in the corrosive solution. The corrosive solution was heated at 80° C. for 30 min and cooled, and then heated again at 80° C. for 30 min. The voltage of 0.6V is applied during 25 min for the measurement.

### EXPERIMENTAL EXAMPLE 2

### Measuring a Contact Resistance

The separator for a fuel cell obtained in the exemplary form and the comparative example was evaluated to determine its contact resistance by making a connection with a gas diffusion layer (GDL).

One sheet of the manufactured separator for a fuel cell was interposed between two collectors and pressurized under the application of a pressure of 10 kgf/cm2, and then measurement of resistance R1 was carried out. Two sheets of the manufactured separator for a fuel cell were interposed between two collectors and pressurized under the application of a pressure of 10 kgf/cm2, and then measurement of resistance R2 was carried out.

The separator-separator contact resistance is calculated according to the following formula.

Separator-Separator Contact Resistance (mΩ·cm²)=[R2(mΩ)-R1(mΩ)]*separator area (cm²)

Three sheets of GDL were interposed between two collectors and pressurized under the application of a pressure of 10 kgf/cm2, and then measurement of resistance R1 was carried out. Two sheets of GDL-one sheet of the separator for a fuel cell obtained from each of the above exemplary forms-two sheets of GDL were interposed successively between two collectors and pressurized under the application of a pressure of 10 kgf/cm², and then measurement of resistance R2 was carried out.

The GDL-separator contact resistance is calculated according to the following formula:

GDL-Separator Contact Resistance (mΩ·cm²)=R2(mΩ)-R1(mΩ)* separator area (cm²)

The final contact resistance was calculated by the sum of the separator-separator contact resistance and the GDL-separator contact resistance.

TABLE 1

| | titanium | titanium | | | |
|---|---|---|---|---|---|
| | carbide | oxide | | contact | corrosion |
| | content | content | hardness | resistance | current |
| | (at %) | (at %) | (GPa) | (Ω/□) | (μA/cm²) |
| exemplary | 37.2 | 7.8 | 3.47 | 7.39 × 10⁻³ | 15.8 |
| form (front | | | | | |
| surface) | | | | | |
| exemplary | 35.4 | 6.2 | 3.43 | 8.08 × 10⁻³ | 15.8 |
| form (rear | | | | | |
| surface) | | | | | |
| Comparative | 11.3 | 11.8 | 2.89 | 4.17 × 10⁻⁵ | 1263 |
| Example (front | | | | | |
| surface) | | | | | |
| Comparative | 9.3 | 13.4 | 3.21 | 3.38 × 10⁻⁵ | 1356 |
| Example (rear | | | | | |
| surface) | | | | | |

As shown in Table 1, in the case of the exemplary form, by using the cyclopentadienyl tris (isopropoxide)titanium as the precursor, the content of the titanium carbide is increased in the titanium carbide coating layer, thereby simultaneously confirming the improvements of the electric conductivity and the corrosion resistance.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method for coating a separator for a fuel cell comprising:
vaporizing a metal carbide precursor to obtain a precursor gas;
introducing a metal carbide coating layer-forming gas including the precursor gas in a reaction chamber; and
applying a voltage to the reaction chamber so that the precursor gas is changed into a plasma state, thereby forming a metal carbide coating layer on either surface or both surfaces of a substrate,
wherein the metal carbide precursor includes a compound having a substituted or non-substituted cyclopentadienyl group.

2. The method of claim 1, wherein:
the metal carbide is selected from the group consisting of a titanium carbide, a chromium carbide, a molybdenum carbide, a tungsten carbide, a copper carbide, and a niobium carbide.

3. The method of claim 1, wherein:
the metal carbide precursor includes a compound represented by Chemical Formula 1: 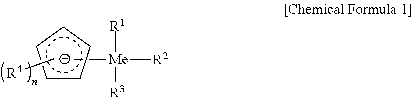
wherein Me is selected from the group consisting of Ti, Cr, Mo, W, Cu, and Nb, R¹ to R³ are independently a substituted or non-substituted C1 to C30 alkyl group, C3 to C30 cycloalkyl group, a C6 to C30 aryl group, C2 to C30 heteroaryl group, a C1 to C10 alkoxy group, a C1 to C10 amino alkyl group,
N is 0 to 4,
R⁴ is a C1 to C30 alkyl group, when n is 2 or more, a plurality of R⁴ is equal to or different from each other.

4. The method of claim 1, wherein:
the metal carbide precursor is selected from the group consisting of (trimethyl) pentamethyl cyclopentadienyl titanium, cyclopentadienyl (cycloheptatrienyl) titanium, tris (dimethylamino) titanium cyclopentadienylide, and cyclopentadienyl tris (isopropoxide) titanium.

5. The method of claim 1, wherein:
the metal carbide precursor is vaporized to obtain the precursor gas in a temperature range of 50° C. to 100° C.

6. The method of claim 1, wherein:
the metal carbide coating layer is formed in a temperature range of 80° C. to 150° C.

7. A separator for a fuel cell obtained by the method of claim 1:
a substrate have two surfaces and a metal carbide coating layer formed on one surface or both surfaces of the substrate, wherein the metal carbide coating layer includes a metal carbide of 5 at % to 50 at % and a metal oxide of 0.01 at % to 15 at %.

8. The separator for the fuel cell of claim 7, wherein:
a thickness of the metal carbide coating layer is in a range of 50 nm to 1000 nm.
